(19) United States
(12) Patent Application Publication
(10) Pub. No.: US 2005/0082601 A1
(43) Pub. Date: Apr. 21, 2005

(54) Split gate field effect transistor with a self-aligned control gate

(76) Inventors: Wen-Ting Chu, Allen Country (TW); Shih-Chang Liu, Aliah Township (TW)

Correspondence Address: DUANE MORRIS, LLP;IP DEPARTMENT, ONE LIBERTY PLACE, PHILADELPHIA, PA, 19103-7396, US

(21) Appl. No.: 10/689,462

(22) Filed: Oct. 20, 2003

(51) Int. Cl. H01L 29/76

(52) U.S. Cl. 257/321

(57) ABSTRACT

A method of forming a split gate field effect transistor and a structure of the split gate field effect transistor are provided. The method of forming the split gate effect transistor firstly provides a substrate having a pair of floating gates, a first conductive material layer between the pair of floating gates, and a first dielectric layer above the first conductive material layer. Then a control gate is formed. The control gate has a second dielectric layer above the control gate, wherein the control gate is self-aligned to the pair of floating gates by using the first and second dielectric layers as an etching hard mask. Finally, a pair of source/drain regions are formed into said substrate and beside said pair of floating gates and said control gate.

### BACKGROUND OF THE INVENTION

1. Field of the Invention

The present invention relates to fabrication of a split gate field effect transistor within a semiconductor integrated circuit. More particularly, the present invention relates to a method for forming the structure of the split gate field effect transistor and a structure of the split gate field effect transistor.

2. Description of the Related Art

Higher level of integration of circuits is the trend in semiconductor fabrication. This purpose can be performed by shrinking device sizes on a chip. Many new techniques have been provided to accomplish the purpose. For example, the Deep Ultra-Violate (DUV) technique is popularly used to enhance the resolution of photolithography in semiconductor fabrication by using a light source having wavelength of 193 nm or 157 nm. By the development of DUV technology, semiconductor manufacturing technology has advanced to deep sub-micron processes. As to process integration, the self-alignment technique is an alternative to improve the level of integration of circuits. Due to the issue of photo misalignment within the manufacturing processes of integrated circuits, more areas of a given die for tolerance of photo misalignment are required. By using a self-alignment technique in semiconductor fabrication, the issue of photo misalignment can be resolved and the size of device can shrink to smaller.

Under the same trend, the size of a non-volatile memory cell has been shrinking by applying new fabrication processes or new structures. A variety of memory devices have been proposed or used in non-volatile memory. Traditionally, Erasable and Programmable Read-Only Memory (EPROM) devices have memory cells which comprise floating-gates, control gates, and source/drain regions. A wide variety of EPROMs are available. One form of EPROMs is a flash EPROM.

Usually, flash memory devices of split-gate structure comprise floating gates and control gates. In the traditional structure, the floating gates and the control gates of the split-gate flash devices are separated by a distance so that the size of the array of cells cannot shrink. Moreover, processes to fabricate the floating gates and control gates of the flash memory devices are very complex and often make devices fail during fabrication. It is difficult to fabricate split-gate structure flash devices in a desired memory cell space. Therefore, some methods and structures for split-gate flash devices have been proposed to eliminate the issues within semiconductor integrated circuit fabrication.

FIG. 1 is a schematic cross-sectional diagram illustrating a split-gate flash cell of U.S. Pub. No. 2002/0064910. The split-gate flash has a structure wherein source/drain regions 11 are formed in a semiconductor substrate 10, a gate insulating film 12 is formed on the substrate 10, a floating gate 14 is formed on the gate insulating film 12, two dielectric layers 15 and 16 are formed above the floating gate 14, dielectric spacers 13 are formed on sidewalls of the floating gate 14, a conductive stud 18 and control gates 17 are formed on the floating gate 14 and the dielectric layer 16. The control gates 17 and the floating gate 14 are insulated from each other by a dielectric film 19. The feature of the prior art is to form a sharp edge on the floating gate 14 to enhance the programming and erasing efficiency of the split-gate flash device.

The control gates 17 are defined by a photolithographic process known to one of ordinary skill in the art. Unfortunately, it is often difficult to form a pair of symmetric control gates in the memory cell. Therefore, photo misalignment can cause one of the pair of control gates 17 to be formed near to, or even above, the conductive stud 18. The overlapping makes the control gates 17 affect the performance of the conductive stud 18, and vice versa. In addition, channel lengths of the control gates 17 are determined during the same photolithographic process. In case where a photo misalignment occurs during the photolithographic process for forming the control gates 17, the channel lengths of the control gates 17 are not symmetric. Therefore, the split-gate flash devices having different channel lengths will perform differently.

FIG. 2 is a schematic cross-sectional diagram illustrating split-gate flash cells of U.S. Pat. No. 6,479,859, called U.S. '859 hereafter. The split-gate flash memory cells have a structure wherein source/drain regions 21 and 22 are formed in a semiconductor substrate 20, a gate dielectric layer 23 is formed above the substrate 20, a floating gate 24 is formed above the gate dielectric layer 23, a dielectric layer 25 is formed above the floating gate 24, and a control gate 27 is formed beside the floating gate 24. The control gate 27 and the floating gate 24 are insulated from each other by a dielectric film 29. The feature of U.S. '859 is to form a spacer control gate 27 by a self-aligned process. In addition, the floating gate 24 has a sharp poly tip enhancing the programming and erasing efficiency of the split-gate flash devices.

Although the method and structure disclosed in U.S. '859 do not use a photolithographic process to form the control gate 27, it uses an etching process to form the spacer control gate 27. The spacer-etching process eliminates the issue of photo misalignment. However, it creates another problem. Usually, after forming the control gate, forming a lightly doped drain (LDD) structure is necessary. The LDD structure is used to reduce or eliminate hot-electron effects. To form the LDD structure, a dielectric spacer is required to form beside the control gate 27. Due to the spacer-shape control gate 27, a normal dielectric spacer can hardly be formed beside the control gate 27. Moreover, a Ti-Salicide process is used to reduce the resistances of the control gate and the drain region. Because of the abnormal shape of the dielectric spacer, the control gate 27 and drain region 22 easily short due to the Ti-Salicide process. Accordingly, it is desirable to resolve the issue of shorting between the control gate and the drain region.

### SUMMARY OF THE INVENTION

A method of forming a split-gate effect transistor comprises providing a substrate having a pair of floating gates, a first conductive material layer between said pair of floating gates, and a first dielectric layer above the first conductive material layer; forming a control gate having a second dielectric layer above said control gate, wherein the control gate is self-aligned to the pair of floating gates by using the first and second dielectric layers as an etching hard mask; and forming a pair of source/drain regions into the substrate and beside the pair of floating gates and the control gate.

A structure of a split-gate effect transistor comprises a substrate; a gate dielectric layer formed above the substrate; a floating gate formed above the gate dielectric layer; an inter-gate dielectric layer formed above the floating gate; a substantially rectangular control gate formed above the inter-gate dielectric layer, wherein a dielectric layer is formed above the control gate and the control gate is offset from the floating gate; and a pair of source/drain regions formed into the substrate and beside the floating gate and the substantially rectangular control gate.

### BRIEF DESCRIPTION OF THE DRAWINGS

FIG. 1 illustrates a schematic cross-sectional structure of a prior art.

FIG. 2 illustrates a schematic cross-sectional structure of another prior art

FIG. 3 is a top view of memory array of the present invention illustrating shallow trench isolations (STI), control gates, floating gates and source/drain regions.

FIGS. 4A-4I show a series of schematic cross-sectional diagrams illustrating the structures of the split-gate field effect transistors of the present invention.

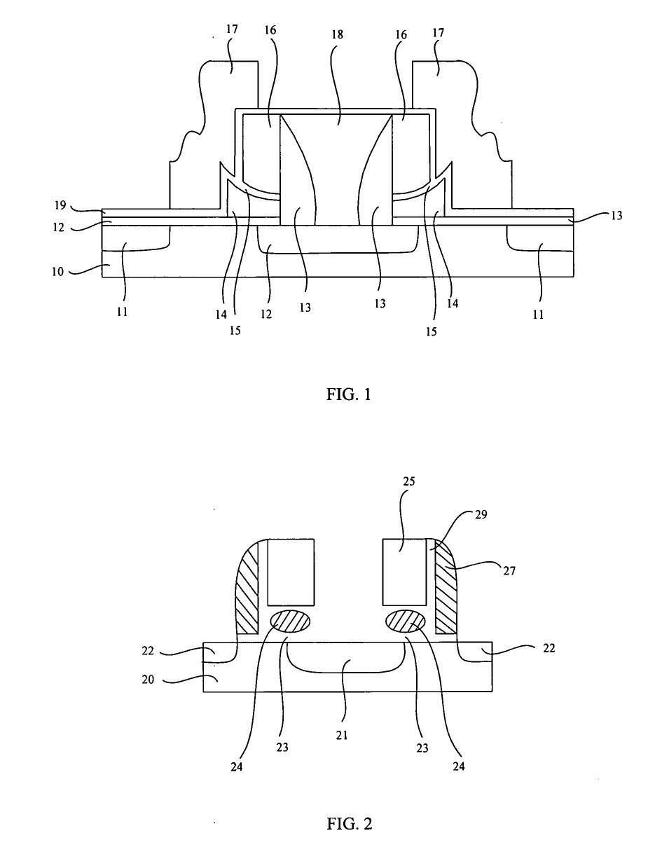

### DESCRIPTION OF THE PREFERRED EMBODIMENT

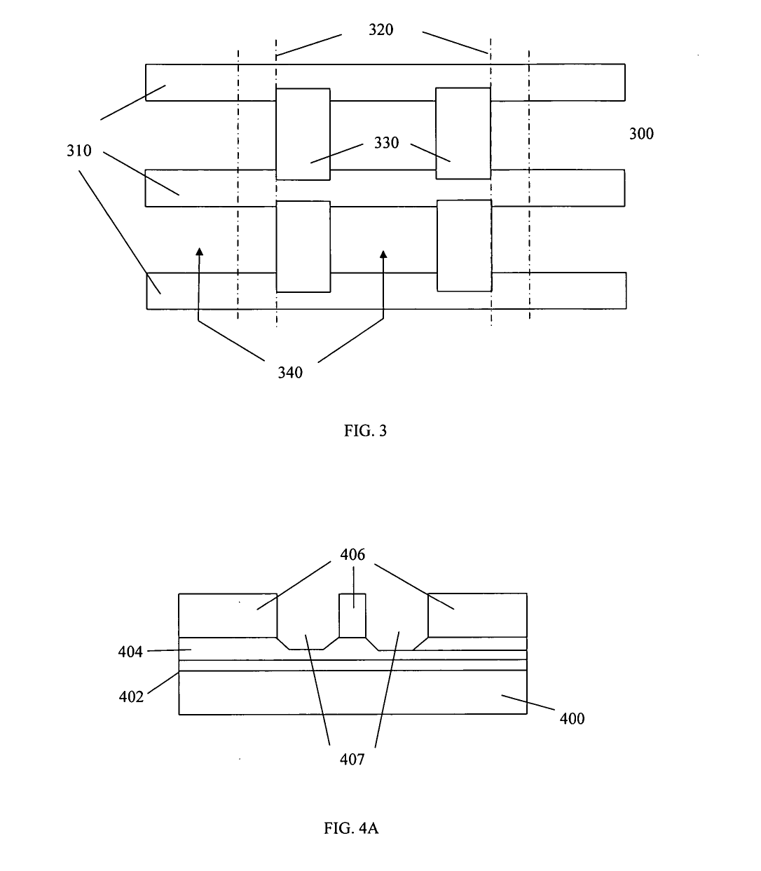

Referring to FIG. 3, it illustrates a top view of a memory array according to one embodiment of the present invention. Shallow trench isolations (STI) structures 403 are formed parallel to each other in a semiconductor substrate 400. Additionally, a pair of control gates 420 of the split gate field effect transistors are formed orthogonally to the STI structures 403. Pairs of floating gates 408 are formed beside the control gates 420 and overlap with the STI structures 403. Finally, source/drain regions 411 and 430 are formed beside the floating gates 408 and the control gates 420.

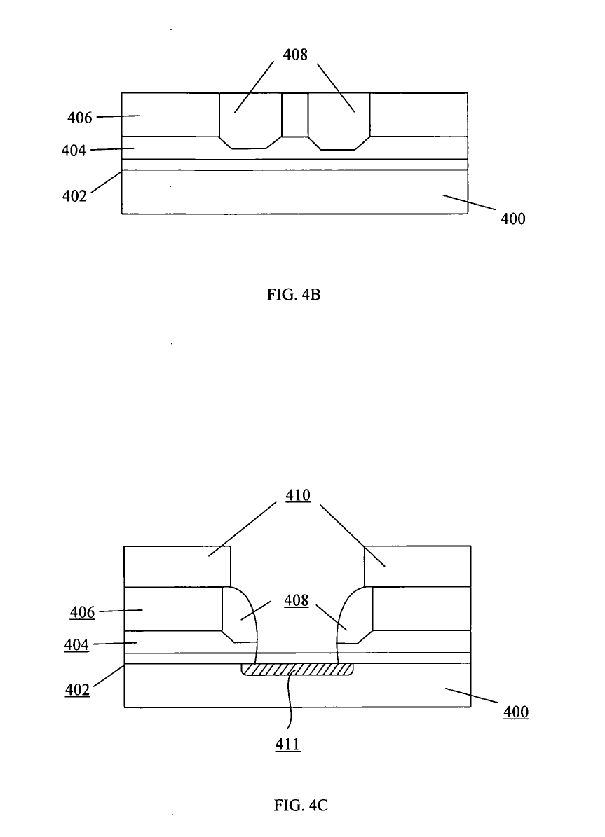

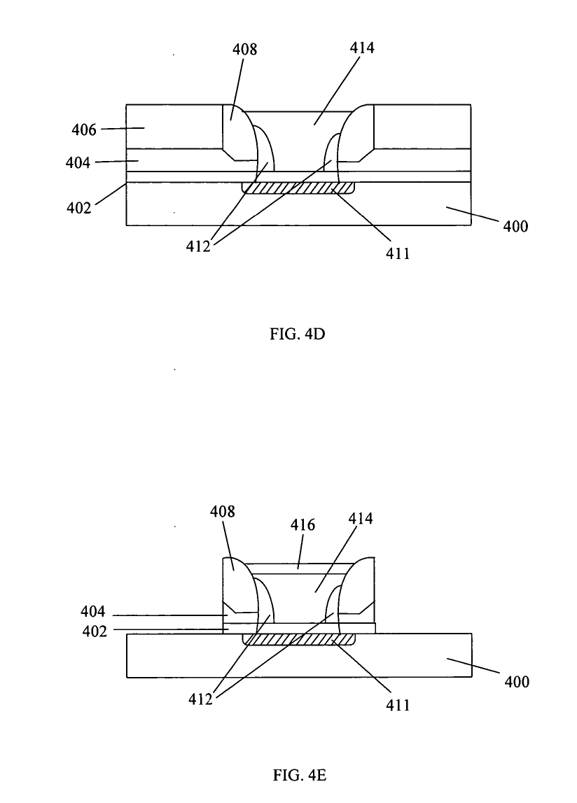

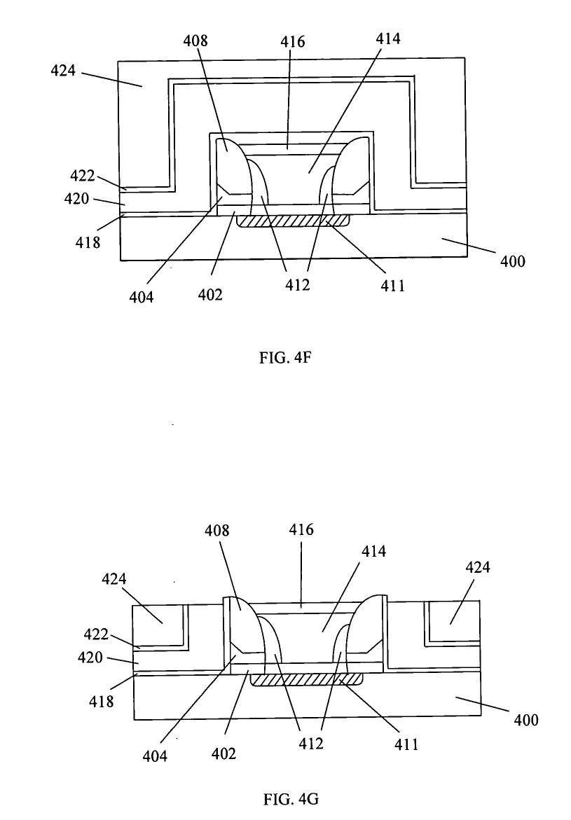

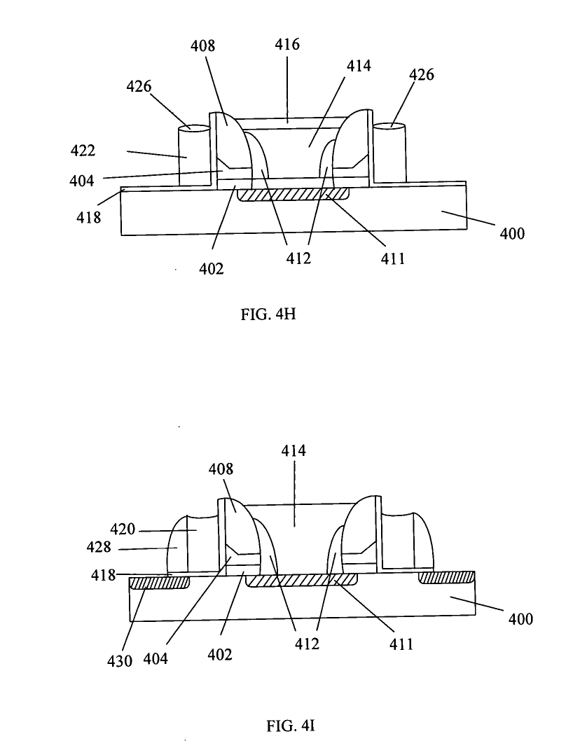

Referring to FIGS. 4A-4I, a series of schematic cross-sectional diagrams illustrate structures of the split-gate field effect transistors of FIG. 3. Moreover, a preferred embodiment of forming a pair of the split gate field effect transistors is performed according to these processes. First a substrate 400 having a pair of floating gates 404, a first conductive material layer 414 between the pair of floating gates 404, and a first dielectric layer 416 above the first conductive material layer 414 is provided. Then a control gate 420 having a second dielectric layer 426 above the control gate 420 is provided, wherein the control gate 420 is self-aligned to the pair of floating gates 404 by using the first and second dielectric layers 416 and 426 as an etching hard mask. Finally, a pair of source/drain regions 411 and 430 are formed into the substrate 400 and beside the pair of floating gates 404 and the control gate 420.

FIG. 4A is a schematic cross-sectional diagram illustrating a structure after forming a pair of trenches 407 in a floating gate layer 404 and a dielectric layer 406.

First, a substrate 400 is provided. The substrate 400 is a semiconductor substrate. It can be, for example a silicon substrate, silicon-germanium substrate, silicon-on-insulator (SOI) substrate, or III-V compound substrate. In some preferred embodiments, the substrate is a silicon substrate. A gate dielectric layer 402 is formed above the substrate 400. The gate dielectric layer 402 can be a silicon oxide layer, silicon nitride layer or any other materials that perform the substantially same function as the gate dielectric layer 402. In some embodiments, it is preferred that the gate dielectric layer 402 is an oxide layer and has a thickness from about 70 angstroms (Å) to about 120 Å. The gate dielectric layer 402 can be formed by a thermal oxidation process using oxygen as a reaction gas. Alternatively, the gate dielectric layer 402 can be formed by an atmospheric or low pressure chemical vapor deposition (APCVD or LPCVD) process using silane (SiH₄) and oxygen as reaction gases. A floating gate layer 404 is formed above the gate dielectric layer 402. The floating gate layer 404 is formed of a conductive material. In some embodiments, it is preferred that the floating gate layer 404 is a polysilicon layer, and has a thickness from about 400 Å to about 1500 Å. In addition, the floating gate layer 404 can be formed by an APCVD or LPCVD process by using SiH₄ as a reaction gas. A dielectric layer 406 is formed above the floating gate layer 404. The dielectric layer 406 can be a silicon nitride layer, silicon oxide layer, or any other materials that can perform substantially the same function of the dielectric layer 406. In some embodiments, it is preferred that the dielectric layer 406 is a silicon nitride layer, and has a thickness from about 2000 Å to about 5000 Å. The dielectric layer 406 can be formed by a traditional APCVD or LPCVD process using dichlorosilane (SiCl₂H₂) and ammonia (NH₃) as reaction gases. Then a photoresist layer (not illustrated) is patterned to form the pair of trenches 407. After the pair of trenches 407 are formed, the photoresist layer is removed by a traditional photoresist removing process. The photoresist layer can be removed by a dry etching process using oxygen, for example, as an etching gas or by a wet etching process using sulfuric acid (H₂SO₄) and hydrogen peroxide (H₂O₂) as etching solutions.

FIG. 4B is a schematic cross-sectional diagram illustrating a structure after filling a pair of planarized layers 408 into the pair of trenches 407.

After the pair of trenches 407 are formed, a filling layer (not illustrated) is used to fill the pair of trenches 407. Then a process of etch back or chemical-mechanical polish (CMP) is used to planarize the surface of the structure of FIG. 4B and to form the planarized layers 408 in the pair of trenches 407. It is preferred that the filling layer is a dielectric layer, such as a silicon oxide layer. The silicon oxide layer can be formed by an APCVD, LPCVD process or a plasma enhanced vapor deposition process (PECVD) using SiH₄ and oxygen as reaction gases. It also can be a spin-on glass (SOG) material. During the etch-back or CMP step, the dielectric layer 406 is used as an etch or CMP stop layer. For the etch-back process, CHF₃, C₂F₆, C₃F₈, or C₄F₈ can be used as an etching gas to remove the oxide layer.

FIG. 4C is a schematic cross-sectional diagram illustrating a structure after forming a common source region 411 of the split gate field effect transistors by using a patterned photoresist layer 410 as an etch mask.

A photoresist layer 410 is formed above the structure of FIG. 4B. A traditional photolithographic process is performed to form a patterned photoresist layer 410 on the structure. Then the patterned photoresist layer 410 is used as an etch mask to remove portions of the planarized layers 408, dielectric layer 406, floating gate layer 404, and the gate dielectric layer 402. It is preferred that the method of removing the portions of the planarized layers 408, dielectric layer 406, floating gate layer 404, and the gate dielectric layer 402 is a sequential anisotropic etching method. Moreover, it is preferred that etching gases of the method have a similar etching rate for the dielectric layer 406 and the planarized layers 408. The removal of the floating gate layer 404 can use chlorine gas (Cl₂) or chlorine silane (SiCl₄) as an etching gas, for example. The removal of the gate dielectric layer can use CHF₃, C₂F₆, C₃F₈, or C₄F₈ as an etching gas. Then an ion implantation process is applied to form the common source region 411 in the substrate 400. Usually, arsenic, phosphorus, or boron can be used as a dopant in forming the common source region 411. Then the photoresist layer 410 is removed by a traditional photoresist removing process. The photoresist layer 410 can be removed by a dry etching process using oxygen as an etching gas or by a wet etching process using H₂SO₄ and H₂O₂ as etching solutions.

FIG. 4D is a schematic cross-sectional illustrating a structure after forming a conductive material layer 414 above the common source region 411.

Beginning with the structure of FIG. 4C, a spacer layer (not illustrated) is formed thereupon. It is preferred that the spacer layer is a dielectric layer, such as silicon oxide or silicon nitride. In some embodiments, silicon oxide is preferred. The silicon oxide layer can be formed by APCVD, LPCVD or PECVD using SiH₄ and oxygen as reaction gases. The silicon oxide layer has a thickness from about 100 Å to about 1000 Å. Then an etching process is used to form a pair of spacers 412 against the sidewalls of the floating gate layer 404. Then the conductive material layer 414 is formed above the structure. A process of etch back or CMP is performed to form the conductive material layer 414 above the common source region 411. The conductive material layer 414 can be polysilicon, tungsten silicide (WSiₓ), or any other materials that can perform substantially the same function of the conductive material layer 414. In some embodiments, it is preferred that the conductive material layer 414 is a polysilicon layer. The polysilicon layer can be formed by an APCVD or LPCVD process using SiH₄ as a reaction gas. For the etch back of the conductive material layer 414, Cl₂ or SiCl₄ can be used as an etching gas to form the stud-like structure of the conductive material layer 414.

FIG. 4E is a schematic cross-sectional diagram illustrating a structure after forming a dielectric layer 416 above the conductive material layer 414 and using the dielectric layer 416 and the pair of planarized layers 408 as an etch hard mask to remove the dielectric layer 406 and portions of the gate dielectric layer 402 and the floating gate layer 404.

The dielectric layer 416 can be formed by using a method of thermal oxidation or a method of chemical vapor deposition. For the method of thermal oxidation, the process can be performed in a furnace or a rapid thermal oxidation chamber by using oxygen as a reaction gas. As to the method of chemical vapor deposition, an APCVD, LPCVD or PECVD process can form the dielectric layer 416. For the purpose of simplifying the process of fabricating the split gate field effect transistor, the method of thermal oxidation is preferred. It has a thickness from about 50 Å to about 300 Å. By using the dielectric layer 416 and pair of planarized layers 408 as an etch hard mask, an etching process is performed to remove the dielectric layer 406 and portions of the gate dielectric layer 402 and the floating gate layer 404. It is preferred that the etching step is a sequential anisotropic etching method. More important, an etching gas having a high etching selectivity for the etch hard mask to the dielectric layer 406, the gate dielectric layer 402 and the floating gate layer 404 is preferred.

FIG. 4F is a schematic cross-sectional diagram illustrating a structure after forming an interpoly dielectric layer 418, a control gate layer 420, a hard mask layer 422 and a sacrificial layer 424 above the structure of FIG. 4E.

Beginning with the structure of FIG. 4E, the interpoly dielectric layer 418 is formed thereupon. The interpoly dielectric layer 418 can be a silicon oxide layer, silicon oxynitride layer, multiple oxide-nitride-oxide layers or any dielectric layers that can perform the substantially same function of the interpoly dielectric layer 418. In some embodiments, it is preferred that the interpoly dielectric layer 418 is a silicon oxide layer and has a thickness from about 100 Å to about 300 Å. The silicon oxide layer can be formed by an APCVD or LPCVD process using SiH₄ and oxygen, for example, as reaction gases. The control gate layer 420 is formed above the interpoly dielectric layer 418. It can be a polysilicon layer, a tungsten silicide layer, or any other material layers that can perform the substantially same function of the control gate layer 420. In some embodiments, it is preferred that the control gate layer 420 is a polysilicon layer. The polysilicon layer has a thickness from about 500 Å to 3000 Å, and can be formed by an APCVD or LPCVD process by using SiH₄ as a reaction gas, for example. Then the hard mask layer 422 is formed above the control gate layer 420. The hard mask layer 422 is a dielectric layer, more particularly, an oxidation resistant layer. It can be a silicon nitride layer, silicon oxynitride layer or other dielectric materials that can perform the substantially same function of the hard mask layer 422. In some embodiments, it is preferred that the hard mask layer is a silicon nitride layer. The silicon nitride layer has a thickness from about 50 Å to about 1000 Å, and can be formed by an APCVD, LPCVD or PECVD process, for example, by using SiCl₂H₂ and ammonia as reaction gases. Then the sacrificial layer 424 is formed above the hard mask layer 422. The sacrificial layer 424 is used to planarize the surface of the structure of FIG. 4F. The sacrificial layer 424 can be an organic anti-reflection coating (ARC) layer, a photoresist layer, a spin-on glass (SOG) layer or the other material layers that can perform substantially same function of planizing the surface of the structure.

FIG. 4G is a schematic cross-sectional diagram illustrating a structure after removing portions of the interpoly dielectric layer 418, the control gate layer 420, the hard mask layer 422 and the sacrificial layer 424 by using a process of etch back or CMP.

Beginning with the structure of FIG. 4F, a process of etch back or CMP is performed to remove portions of the interpoly dielectric layer 418, the control gate layer 420, the hard mask layer 422 and the sacrificial layer 424 until the dielectric layer 416 and the pair of planarized layers 408 are exposed. Moreover, the L-shape interpoly dielectric layer 418, the control gate layer 420, and the hard mask layer 422 are formed beside the floating gate layer 404 and the pair of planarized layers 408. It is preferred that the etch-back process uses an etching gas having a similar etching rate for the sacrificial layer 424, the hard mask layer 422, and the control gate layer 420. Similarly, CMP should also use polishing slurry having a similar removal rate for these layers.

FIG. 4H is a schematic cross-sectional diagram illustrating a structure after removing the sacrificial layer 424, the hard mask layer 422, and a portion of the control gate layer 420, and forming a dielectric layer 426 above the control gate layer 420.

Beginning with the structure of FIG. 4G, the sacrificial layer 424 is removed by using a photoresist removing process, if the sacrificial layer 424 is an organic ARC or photoresist layer. The photoresist removing process can be performed by using oxygen as a reaction gas in a plasma chamber or using sulfuric acid (H₂SO₄) and hydrogen peroxide (H₂O₂) as etching solutions in a wet bench. Because the exemplary hard mask layer 422, dielectric layer 416 and planarized layers 408 are oxidation resistant layers, (more particularly, the hard mask layer 422 is a nitride layer), an oxide layer 426 can be formed on the top of the control gate layer 420 by thermal oxidation by using the hard mask layer 422, the dielectric layer 416, and the pair of planarized layers 408 as an oxidation resistant layer. Because the oxide layer 426 is formed by thermal oxidation, the oxide layer 426 is elliptical, or is thicker at a middle portion than at an edge portion as shown in FIG. 4H. The oxide layer 426 has a thickness from about 50 Å to about 400 Å, and can be formed by using oxygen as a reaction gas. After the formation of the oxide layer 426, the hard mask layer 422 and a portion of the control gate layer 420 can be removed by using the oxide layer 426, the pair of planarized layers 408, and the dielectric layer 416 as an etching hard mask. Then a substantially rectangular control gate is formed beside the floating gate layer 404.

FIG. 4I is a schematic cross-sectional diagram illustrating a structure after forming a lightly doped drain (LDD) spacer 428, and before performing a Ti-Salicide process on the structure.

Beginning with the structure of FIG. 4H, a spacer layer (not illustrated) is formed thereupon. The spacer layer is a dielectric layer. It can be a silicon oxide layer or a silicon nitride layer, for example, formed by PECVD using SiH₄ and oxygen or SiCl₂H₂ and ammonia as reaction gases respectively. It has a thickness from about 100 Å to about 1000 Å. Then an etch-back process is performed to form the spacers 428. Then an ion implantation process is performed to form the drain region 430 in the substrate 400. Usually, arsenic, phosphorus, or boron can be used as a dopant in forming the drain region 430. Before the Ti-Salicide process, a cleaning process is used to remove the oxide layer 426, and the dielectric layer 416. If the dielectric layer 416 and the oxide layer 426 are silicon oxide layers, both of them can be removed by using hydrofluoric acid (HF) as an etching solution. Because of the removal of the oxide layer 426, the control gate layer 420 has a concave top surface.

According to some embodiments of the method disclosed above, a substantially rectangular control gate is formed by a self-aligned process. The issue of photolithographic misalignment is resolved. Moreover, the exemplary method can also avoid the problem of shorting between control gates and drain regions.

Although the present invention has been described in terms of exemplary embodiments, it is not limited thereto. Rather, the appended claims should be constructed broadly to include other variants and embodiments of the invention which may be made by those skilled in the field of this art without departing from the scope and range of equivalents of the invention.

1. A method of forming a split gate field effect transistor, comprising:
providing a substrate having a pair of floating gates, a first conductive material layer between said pair of floating gates, and a first dielectric layer above said first conductive material layer;
forming a control gate having a second dielectric layer above said control gate, wherein said control gate is self-aligned to said pair of floating gates by using said first and second dielectric layers as an etching hard mask; and
forming a pair of source/drain regions into said substrate and beside said pair of floating gates and said control gate.

2. The method of claim 1, wherein each of said first dielectric layer and said second dielectric layer comprises a silicon oxide layer.

3. The method of claim 2, wherein said second dielectric layer is formed by a method of thermal oxidation.

4. The method of claim 2, wherein said silicon oxide layer has a thickness from about 50 angstroms to about 400 angstroms.

5. The method of claim 1, wherein said second dielectric layer is thicker at a middle portion than at an edge portion.

6. The method of claim 1, wherein said step of forming said control gate comprises:
forming a second conductive material layer above said substrate;
forming a hard mask layer above said second conductive material layer;
removing portions of said hard mask layer and said second conductive material layer;
forming said second dielectric layer above said second conductive material layer; and
removing a remaining portion of said hard mask layer and an additional portion of said second conductive material layer by using said first dielectric layer and said second dielectric layer as said etching hard mask.

7. The method of claim 6, wherein said second dielectric layer is formed by using said hard mask layer as an oxidation resistant layer.

8. The method of claim 7, wherein said hard mask layer comprises a silicon nitride layer.

9. The method of claim 6, wherein said step of removing portions of said hard mask layer and said second conductive material layer comprises:
forming a sacrificial layer above said hard mask layer;
removing portions of said sacrificial layer, said hard mask layer and said second conductive material layer;
removing a remaining portion of said sacrificial layer;

10. The method of claim 9, wherein said sacrificial layer is used to planarize a surface of said substrate

11. The method of claim 10, wherein said sacrificial layer comprises an organic material layer.

12. The method of claim 11, wherein said organic material layer comprises a photoresist.

13. The method of claim 10, wherein said sacrificial layer comprises a spin-on glass layer.

14. A split gate field effect transistor, comprising:
a substrate;
a gate dielectric layer formed above said substrate;
a floating gate formed above said gate dielectric layer;
an inter-gate dielectric layer formed above said floating gate;
a substantially rectangular control gate formed above said inter-gate dielectric layer, wherein a dielectric layer is formed above said control gate and said control gate is offset said floating gate; and
a pair of source/drain regions formed into said substrate and beside said floating gate and said substantially rectangular control gate.

15. The split gate field effect transistor of claim 14 wherein said substantially rectangular control gate does not overlay said floating gate.

16. The split gate field effect transistor of claim 14 wherein said substantially rectangular control gate has a concave top surface.

17. The split gate field effect transistor of claim 14 wherein said substantially rectangular control gate is formed by using a dielectric layer above said substantially rectangular control gate as an etching hard mask.

18. The split gate field effect transistor of claim 14, wherein said dielectric layer comprises a silicon oxide layer.

19. The split gate filed effect transistor of claim 18, wherein said silicon oxide layer is formed by a method of thermal oxidation.

20. The split gate field effect transistor of claim 18, wherein said silicon oxide layer has a thickness from about 50 angstroms to about 400 angstroms.

21. The split gate field effect transistor of claim 17, wherein said dielectric layer is thicker at a middle portion than at an edge portion.

22. A structure for forming a split gate effect transistor, comprising:
a substrate having a pair of floating gates, a first conductive material layer between said pair of floating gates, and a first dielectric layer above said first conductive material layer;
a second conductive material layer formed above said substrate;
a hard mask layer formed above said second conductive material layer; and
a sacrificial layer formed above said hard mask layer.

23. The structure of claim 22, wherein said sacrificial layer is used to planarize a surface of said substrate.

24. The structure of claim 23, wherein said sacrificial layer comprises an organic material layer.

25. The structure of claim 24, wherein said organic material layer comprises a photoresist.

26. The structure of claim 23, wherein said sacrificial layer comprises a spin-on glass layer.

27. The structure of claim 22, wherein said hard mask layer comprises an oxidation resistant layer.

28. The structure of claim 27, wherein said oxidation resistant layer comprises a silicon nitride layer.

29. The structure of claim 22, wherein said first dielectric layer has a thickness from about 50 angstroms to about 400 angstroms.

30. The structure of claim 22, wherein said second conductive material layer completely covers said pair of floating gates and said first dielectric layer, said hard mask completely covers said second conductive material layer, and said sacrificial layer completely covers said hard mask layer.

31. The structure of claim 22, wherein said second conductive material layer, said hard mask layer, and said sacrificial layer are offset from said pair of floating gates and said first conductive material layer

32. The structure of claim 31, wherein said second conductive material layer and said hard mask layer have a cross-section formed in substantially L shape.

33. The structure of claim 32, wherein said sacrificial layer contacts with two surfaces of said L shape of said hard mask layer.
